(19) United States
(12) Patent Application Publication
(10) Pub. No.: US 2011/0155048 A1
(43) Pub. Date: Jun. 30, 2011

(54) MANUFACTURING APPARATUS AND MANUFACTURING METHOD OF SILICON CARBIDE SINGLE CRYSTAL

(75) Inventor: Jun KOJIMA, Iwakura-city (JP)

(73) Assignee: DENSO CORPORATION, Kariya-city (JP)

(21) Appl. No.: 12/956,007

(22) Filed: Nov. 30, 2010

(30) Foreign Application Priority Data
Dec. 25, 2009 (JP) 2009-294800

(51) Int. Cl. C30B 23/00

(52) U.S. Cl. 117/84; 118/716

(57) ABSTRACT

A silicon carbide single crystal manufacturing apparatus includes a pedestal on which a seed crystal is disposed and a heating crucible disposed on an upstream side of a flow channel of source gas with respect to the pedestal. The heating crucible supplies the source gas to the seed crystal by introducing the source gas from an upstream end of a hollow cylindrical member and discharging the source gas from a downstream end of the hollow cylindrical member. A diameter narrowing part is disposed on the downstream end and has an opening portion that is smaller than an opening size of the hollow cylindrical member. The whole opening portion of the diameter narrowing part is included in a region that is defined by projecting an outer edge of the pedestal in a center axis direction of the heating crucible.

### CROSS REFERENCE TO RELATED APPLICATIONS

The present application is based on and claims priority to Japanese Patent Application No. 2009-294800 filed on Dec. 25, 2009, the contents of which are incorporated in their entirety herein by reference.

### BACKGROUND OF THE INVENTION

1. Field of the Invention

The present invention relates to a manufacturing apparatus and a manufacturing method of silicon carbide single crystal.

2. Description of the Related Art

Conventionally, as a SiC single crystal manufacturing apparatus, for example, a manufacturing apparatus described in JP-A-2004-339029 (corresponding to US 2004/194694 A) has been suggested. In the SiC single crystal manufacturing apparatus, source gas of SiC is introduced to a heating crucible through an introducing pipe, the source gas is decomposed in the heating crucible, and the decomposed source gas is introduced to a seed crystal disposed in a reaction crucible.

FIG. 6 is a schematic cross-sectional view showing a state of source gas flow in a conventional SiC single crystal manufacturing apparatus. In the conventional SiC single crystal manufacturing apparatus, a downstream side of a flow channel of the source gas in a heating crucible J1 is fully opened. Therefore, as shown by arrows in FIG. 6, the source gas flow uniformly hits against the seed crystal J3 disposed in a reaction crucible J2. Thus, a growth of the SiC single crystal on the seed crystal J3 tends to be a flat growth in which a surface of the SiC single crystal flatly grows or a concave growth in which a center portion of the surface of the SIC single crystal concavely grows. However, in the flat growth and the concave growth, there is a problem that a macroscopic defect such as multiple system or a microscopic defect such as basal surface dislocation extends from an outer peripheral portion toward a center portion. Therefore, it is preferable that the growth of the SiC single crystal becomes a growth form in which the SiC single crystal can grow while restricting a crystal defect from the outer peripheral portion, that is, a convex growth in which the growth surface of the SiC single crystal becomes convexly grows.

### SUMMARY OF THE INVENTION

In view of the foregoing problems, it is an object of the present invention to provide a manufacturing apparatus and a manufacturing method of a SiC single crystal in which the SiC single crystal can convexly grow.

According to an aspect of the present invention, a SiC single crystal manufacturing apparatus grows a SiC single crystal on a surface of a seed crystal that is made of a SiC single crystal substrate by supplying source gas of SiC from under the seed crystal and includes a pedestal and a heating crucible. The seed crystal is disposed on the pedestal. The heating crucible is disposed on an upstream side of a flow channel of the source gas with respect to the pedestal. The heating crucible includes a hollow cylindrical member and a diameter narrowing part. The hollow cylindrical member has an upstream end and a downstream end. The heating crucible supplies the source gas to the seed crystal by introducing the source gas from the upstream end of the hollow cylindrical member and discharging the source gas from the downstream end of the hollow cylindrical member. The diameter narrowing part is disposed on the downstream end of the hollow cylindrical member and has an opening portion that is smaller than an opening size of the hollow cylindrical member. The whole opening portion of the diameter narrowing part is included in a region that is defined by projecting an outer edge of the pedestal in a center axis direction of the heating crucible.

In the SiC single crystal manufacturing apparatus, the diameter narrowing part is disposed on the downstream end of the hollow cylindrical member and a flux of the source gas can have an in-plane distribution on a growth surface of the SiC single crystal owing to the diameter narrowing part. Thus, the SiC single crystal can convexly grow.

According to another aspect of the present invention, in a method of manufacturing a SiC single crystal, a seed crystal that is made of a SiC single crystal substrate is disposed on a pedestal, and heating crucible is disposed on an upstream side of a flow channel of source gas of SiC with respect to the pedestal. The heating crucible includes a hollow cylindrical member and a diameter narrowing part. The hollow cylindrical member has an upstream end and a downstream end. The heating crucible supplies the source gas to the seed crystal by introducing the source gas from the upstream end of the hollow cylindrical member and discharging the source gas from the downstream end of the hollow cylindrical member. The diameter narrowing part is disposed on the downstream end of the hollow cylindrical member and has an opening portion that is smaller than an opening size of the hollow cylindrical member. The SiC single crystal is grown on a surface of the seed crystal in such a manner that a flux of the source gas has an in-plane distribution on a growth surface of the SiC single crystal by supplying the source gas through the opening portion of the diameter narrowing part.

When the SiC single crystal is manufactured by the above-described method, the SiC single crystal can convexly grow.

### BRIEF DESCRIPTION OF THE DRAWINGS

Additional objects and advantages of the present invention will be more readily apparent from the following detailed description of preferred embodiments when taken together with the accompanying drawings. In the drawings:

FIG. 1 is a cross-sectional view of a SiC single crystal manufacturing apparatus according to a first embodiment of the present invention;

FIG. 2 is a diagram showing a state of a SiC single crystal during manufacture with the SiC single crystal manufacturing apparatus shown in FIG. 1;

FIG. 3 is a diagram showing a state of a SiC single crystal during manufacture with a SiC single crystal manufacturing apparatus according to a second embodiment of the present invention;

FIG. 4 is diagram showing a state of a SiC single crystal during manufacture with a SiC single crystal manufacturing apparatus according to a third embodiment of the present invention;

FIG. 5 is a diagram showing a state of a SiC single crystal during manufacture with a SiC single crystal manufacturing apparatus according to another example of the third embodiment; and

FIG. 6 is a diagram showing a state of source gas flow in a SiC single crystal manufacturing apparatus according to a related art.

### DETAILED DESCRIPTION OF THE PREFERRED EMBODIMENTS

### First Embodiment

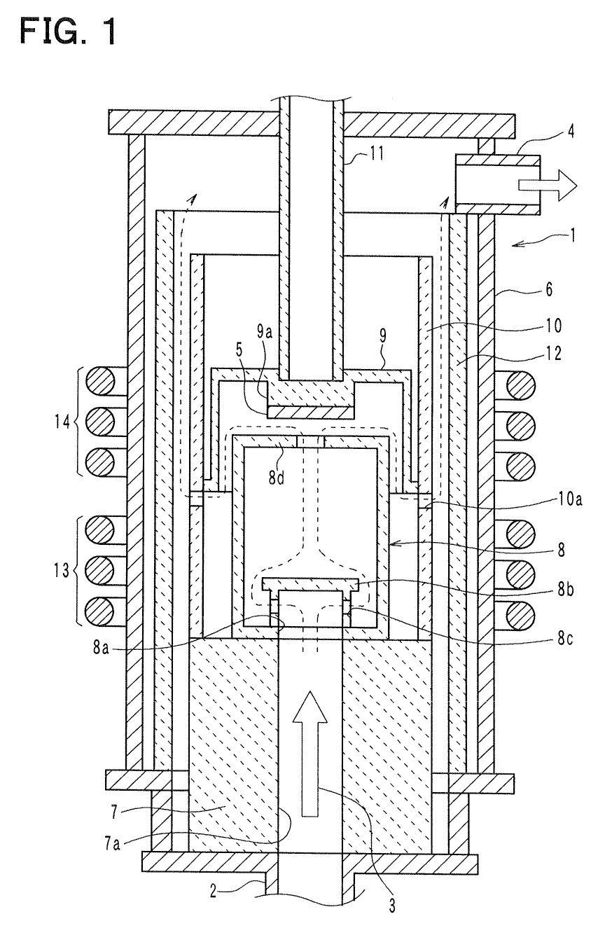

A SiC single crystal manufacturing apparatus 1 according to a first embodiment of the present invention will be described with reference to FIG. 1.

The SiC single crystal manufacturing apparatus 1 supplies source gas 3 of SiC with carrier gas through an inlet 2 provided at a bottom and discharging the carrier gas and the source gas 3 through an outlet 4, and thereby causes a crystal growth of a SiC single crystal on a seed crystal 5. The source gas 3 of SiC includes Si and C. For example, the source gas 3 is mixed gas of silane-based gas including silane and hydrocarbon-based gas including propane. The seed crystal 5 is disposed in the SiC single crystal manufacturing apparatus 1 and is made of a SiC single crystal substrate.

The SiC single crystal manufacturing apparatus 1 includes a vacuum chamber 6, a first heat insulator 7, a heating crucible 8, a reaction crucible 9, an external wall 10, a pipe 11, a second heat insulator 12, a first heating device 13, and a second heating device 14.

The vacuum chamber 6 is made of quartz and has a hollow cylindrical shape. The carrier gas and the source gas 3 can be introduced into and discharged from the vacuum chamber 6. The vacuum chamber 6 houses other components of the SiC single crystal manufacturing apparatus 1. A pressure in a space in the vacuum chamber 6 can be reduced by vacuuming. The inlet 2 of the source gas 3 is provided at the bottom of the vacuum chamber 6 and the outlet 4 of the source gas 3 is provided at an upper portion (specifically, an upper portion of a sidewall).

The first heat insulator 7 has a tube shape including a cylindrical shape. The first heat insulator 7 is coaxially-arranged with the vacuum chamber 6, and a hollow part of the first heating insulator 7 configurates a source gas introducing pipe 7a. The first heat insulator 7 is made of, for example, graphite or graphite whose surface is coated with TaC (tantalum carbide).

The heating crucible 8 is made of, for example, graphite or graphite whose surface is coated with TaC. The heating crucible 8 is disposed on an upstream side of a flow channel of the source gas 3 with respect to the reaction crucible 9. The heating crucible 8 removes particles included in the source gas 3 and decomposes the source gas 3 until the source gas 3 supplied from the inlet 2 is introduced to the seed crystal 5.

The heating crucible 8 includes a hollow cylindrical member. The hollow cylindrical member has an upstream end and a downstream end. In the present embodiment, the heating crucible 8 includes a cylindrical member having a bottom at an upstream end. The heating crucible 8 has a gas inlet 8a at the bottom and the gas inlet 8a is communicated with the hollow portion of the first heat insulator 7. The source gas passing through the hollow portion of the first heat insulator 7 is introduced into the heating crucible 8 through the gas inlet 8a. The heating crucible 8 has a baffle 8b. By collision of the source gas 3 with the baffle 8b, the flow channel of the source gas 3 is curved, removal of particles included in the source gas 3 and mixing of the source gas 3 are performed, and supplying the undecomposed source gas 3 toward the seed crystal 5 is restricted.

For example, the baffle 8b has a cylindrical shape with a bottom and has a plurality of communication holes 8c in a sidewall. The baffle 8b is disposed in such a manner that an open end portion of the baffle 8b, that is, an end portion opposite the bottom faces the gas inlet 8a at the bottom of the heating crucible 8. In this configuration, the source gas 3 introduced from the gas inlet 8a collides against a bottom surface of the baffle 8b. Thus, particles colliding with the baffle 8b fall to the bottom of the heating crucible 8 and are removed from the source gas 3. The source gas 3 whose flow channel is changed from a direction parallel to an axial direction of the heating crucible 8 to a vertical direction is introduced to a downstream side of the flow channel in the heating crucible 8 with respect to the baffle 8b through the communication holes 8c.

The heating crucible 8 further includes a diameter narrowing part 8d. The diameter narrowing part 8d is disposed on the downstream end of the hollow cylindrical member of the heating crucible 8. In other words, the diameter narrowing part 8d is disposed at an end portion of the heating crucible 8 opposite the bottom of the cylindrical member and adjacent to the reaction crucible 9, that is, the end portion located on the downstream side of the flow channel of the source gas 3. The diameter narrowing part 8d has an opening portion smaller than an opening size of the hollow cylindrical member. The heating crucible 8 supplies the source gas 3 to the seed crystal 5 by introducing the source gas 3 from the upstream end of the hollow cylindrical member and discharging the source gas 3 from the downstream end of the hollow cylindrical member through the opening portion of the diameter narrowing part 8d. The diameter narrowing part 8d decreases an opening size of the end portion of the heating crucible 8 on the downstream side of the flow channel of the source gas 3 to be smaller than a diameter of the seed crystal 5. The diameter narrowing part 8d can limit the source gas 3 so that flux of the source gas 3 has an in-plane distribution on a growth surface of the SiC single crystal. Thus, the source gas 3 selectively hits against a center portion of the seed crystal 5.

The diameter narrowing part 8d has the opening portion at a position corresponding to a pedestal 9a on which the seed crystal 5 is disposed. The opening portion of the diameter narrowing part 8d is smaller than a dimension of the pedestal 9a. In other words, the diameter narrowing part 8a is formed in such a manner that the whole opening portion of the diameter narrowing part 8d is included in a region defined by projecting an outer edge of the pedestal 9a in a center axis direction of the heating crucible 8. Thus, when the seed crystal 5 is disposed on the pedestal 9a, the opening portion of the diameter narrowing part 8d is disposed at a position facing the seed crystal 5, and the source gas 3 introduced from the opening portion of the diameter narrowing part 8d can hit against a part of the seed crystal 5 with certainty.

The reaction crucible 9 defines a space in which the source gas 3 flows and has a tube shape with a bottom. The reaction crucible 9 has a cylindrical shape with a bottom and is coaxially-arranged with the center axis of the heating crucible 8. The reaction crucible 8 is made of, for example, graphite or graphite whose surface is coated with TaC. The pedestal 9a having a circle shape is disposed at a bottom of the reaction crucible 9, and the seed crystal 5 having a dimension similar to the pedestal 9a is attached to the pedestal 9a. An end of the heating crucible 8 is inserted into the opening portion of the reaction crucible 9. The SiC single crystal grows on the surface of the seed crystal 5 disposed at the bottom of the reaction crucible 9 using a space provided between the end of the heating crucible 8 and the bottom of the reaction crucible 9 as a reaction chamber.

The external wall 10 is made of graphite or graphite whose surface is coated with TaC. The external wall 10 surrounds the peripheries of the heating crucible 8 and the reaction crucible 9 and introduces the source gas 3 introduced to the reaction crucible 9 toward the outlet 4. The external wall 10 has a plurality of communication holes 10a arranged at regular intervals in a circumferential direction. At a portion of the external wall 10 located above the communication holes 10a, that is, at the portion of the external wall 10 adjacent to the reaction crucible 9, an inner wall of the external wall 10 is in contact with the periphery of the opening portion of the reaction crucible 9, and there is no clearance between the reaction crucible 9 and the external wall 10. Thus, remains of the source gas 3 after supplied to the seed crystal 5 in the reaction crucible 9 is introduced to an outside of the external wall 10 through the communication hole 10a, and is introduced to the outlet 4 through a clearance between the external wall 10 and the second heat insulator 12 not through a space between the reaction crucible 9 and the external wall 10.

An end of the pipe 11 is coupled with a portion of the bottom of the reaction crucible 9 opposite from the heating crucible 8, and the other end of the pipe 11 is coupled with a rotational lifting mechanism that is not shown. Accordingly, the reaction crucible 9, the seed crystal 5 and the SiC signal crystal can be rotated and lifted with the pipe 11. A temperature of the growth surface of the SIC single crystal is controlled to be a temperature appropriate to the growth of the SiC single crystal and to have a desired temperature distribution. The pipe 11 is also made of, for example, graphite or graphite whose surface is coated with TaC.

The second heat insulator 12 is disposed along a sidewall of the vacuum chamber 6 and has a hollow cylindrical shape. The second heat insulator 12 surrounds the most part of the first heat insulator 7, the heating crucible 8, the reaction crucible 9, and the external wall 10. The second heat insulator 12 is also made of, for example, graphite or graphite whose surface is coated with TaC.

The first and second heating devices 13 and 14 include, for example, induction heating coils or heaters, and surround the vacuum chamber 6. Temperatures of the first and second heating devices 13 and 14 can be controlled independently. Thus, the temperature can be controlled more finely. The first heating device 13 is disposed at a position corresponding to the heating crucible 8. The second heating device 14 is disposed at a position corresponding to the reaction chamber provided by the reaction crucible 9. By controlling the first and second heating devices 13 and 14, the temperature distribution of the reaction chamber can be controlled to be a temperature appropriate to the growth of the SiC single crystal and the temperature of the heating crucible 8 can be controlled to be a temperature appropriate to the removal of the particles.

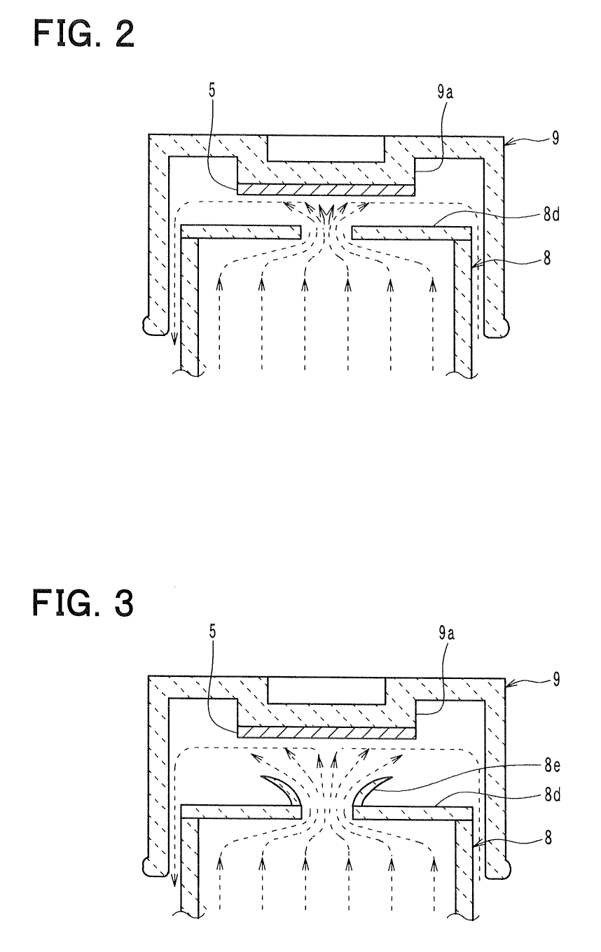

Next, a manufacturing method of the SiC single crystal with the SiC signal crystal manufacturing apparatus 1 will be described with reference to FIG. 2. FIG. 2 shows only the vicinity of the end portion of the heating crucible 8 adjacent to the reaction crucible 9.

Firstly, the first and second heating devices 13 and 14 are controlled so that a predetermined temperature distribution is provided. In other words, the temperature is controlled so that the SiC single crystal grows on the surface of the seed crystal 5 by recrystallizing the source gas 3 and a recrystallizing rate is higher than a subliming rate in the heating crucible 8.

In addition, while keeping a pressure in the vacuum chamber 6 to a predetermined pressure, the source gas 3 is introduced through the gas introducing pipe 7a with introducing carrier gas of inert gas such as Ar gas and etching gas such as hydrogen gas as necessary. Accordingly, the source gas 3 flows as shown by dashed arrows in FIG. 1 and FIG. 2 and is supplied to the seed crystal 5 so that the SiC single crystal grows.

At this time, the source gas 3 may include particles. The particles are formed by, for example, condensation of Si-component or C-component in the source gas 3, exfoliation of an inner surface of a passage of a member made of graphite, and exfoliation of SiC attached to the inner surface of the passage. The particles are included in the source gas 3 and flow with the source gas 3. However, because the source gas 3 including the particles is collided against the baffle 8b and the particles fall, the particles are restricted from reaching the surface of the seed crystal 5 and the growth surface of the SiC single crystal. Thus, the SiC single crystal having a high quality can be manufactured.

In the present embodiment, the diameter narrowing part 8d is provided at the end portion of the heating crucible 8 adjacent to the reaction crucible 9, and the source gas 3 hits against, for example, near the center of the seed crystal 5 as shown by the dashed arrows in FIG. 2 owing to the diameter narrowing part 8d. Thus, the SiC single crystal that grows on the seed crystal 5 can grow from one crystal nucleus, and the SiC single crystal can convexly grow in such a manner that the growth surface of the SiC single crystal has a convex shape.

As described above, in the present embodiment, the diameter narrowing part 8d is provided at the end portion of the heating crucible 8 adjacent to the reaction crucible 9, and the flux of the source gas 3 has the in-plane distribution on the growth surface of the SiC single crystal owing to the diameter narrowing part 8. Accordingly, the SiC single crystal can convexly grow. Thus, a generation of an issue that crystals glowing from a plurality of growth nuclei form a polycrystal can be restricted.

### Second Embodiment

A SiC single crystal manufacturing apparatus 1 according to a second embodiment of the present invention will be described with reference to FIG. 3. In the present embodiment, a configuration of the heating crucible 8 is changed from the first embodiment and the other is similar to the first embodiment. Thus, only different part will be described.

FIG. 3 shows only the vicinity of the end portion of the heating crucible 8 adjacent to the reaction crucible 9.

The diameter narrowing part 8d has a surface facing the pedestal 9a. The diameter narrowing part 8d has a taper part 8e on the surface. An opening size of the taper part 8e increases from the opening portion of the diameter narrowing part 8d toward the pedestal 9a. Owing to the taper part 8e, the flux of the source gas 3 gradually decreases with spreading from the opening portion of the diameter narrowing part 8d in a radial direction. Thus, the flux of the source gas 3 can hit against the seed crystal 5 with the distribution, and the source gas 3 can be restricted from hitting only against a part of the growth surface of the SiC single crystal near the opening portion of the diameter narrowing part 8d.

For example, in a case where only the diameter narrowing part 8d is provided as the first embodiment, the source gas 3 may concentrically hit against a position of the growth surface of the SiC single crystal corresponding to the opening portion of the diameter narrowing part 8d. In this case, the SiC single crystal may locally grow into a conical shape at a portion where the source gas 3 concentrically hit. However, by providing the taper part 8e so that the flux of the source gas 3 has an in-plane distribution on the growth surface of the SiC single crystal as the present embodiment, the source gas 3 can be restricted from concentrically hitting against the part of the growth surface of the SiC single crystal near the opening portion of the diameter narrowing part 8d. Therefore, the SiC single crystal can be prevented from locally glowing into the conical shape, and the convex growth can be performed at the whole surface of the SiC single crystal.

### Third Embodiment

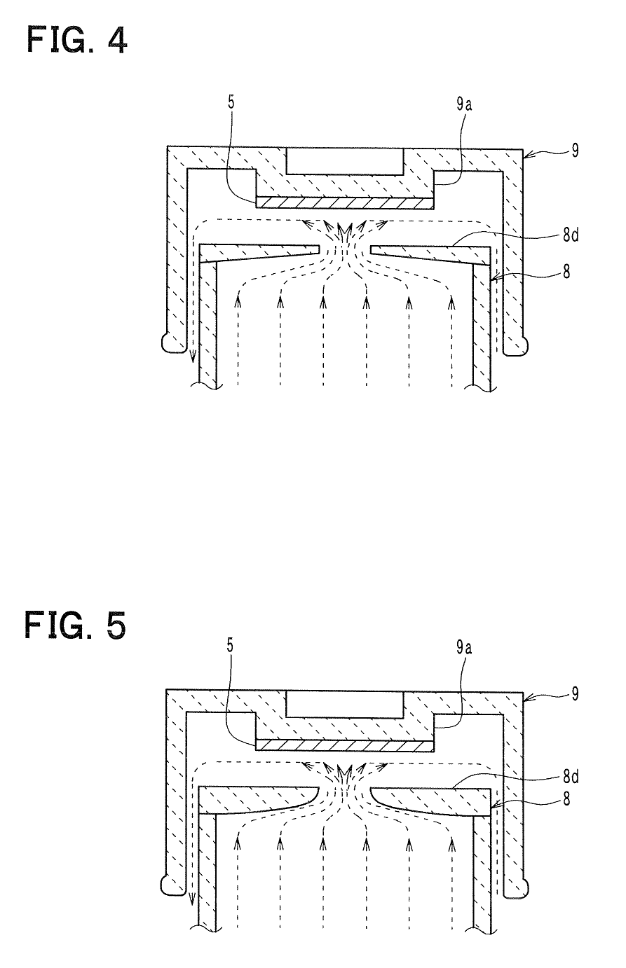

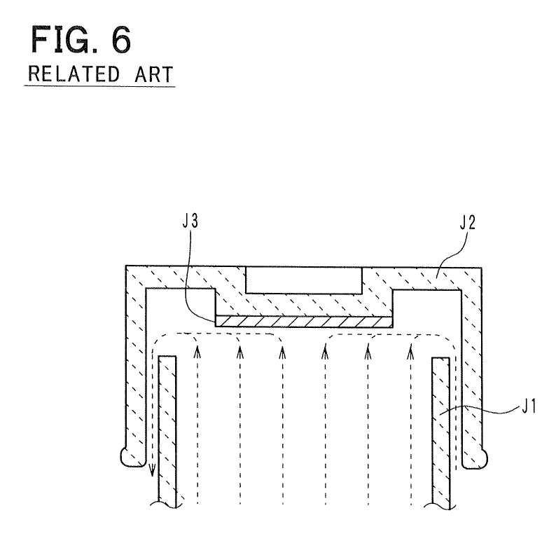

A SiC single crystal manufacturing apparatus according to a third embodiment of the present invention will be described with reference to FIG. 4. Also in the present embodiment, a configuration of the heating crucible 8 is changed from the first embodiment and the other is similar to the first embodiment. Thus, only different part will be described.

FIG. 4 shows only the vicinity of the end portion of the heating crucible 8 adjacent to the reaction crucible 9.

In the present embodiment, a thickness of the diameter narrowing part 8d decreases toward a center axis direction of the heating crucible 8. In a case where the heating crucible 8 has the diameter narrowing part 8d having the above-described thickness, when a growth of the SiC single crystal continues, the opening size of the opening portion of the diameter narrowing part 8d is gradually increased by etching by hydrogen, thermal etching or, supplying a part of the diameter narrowing part 8d that sublimes as source. Accordingly, with the growth of the SiC single crystal, that is, with a gradual increase in a diameter of the SiC single crystal, the opening size of the opening portion of the diameter narrowing part 8d gradually increases. Thus, at a large region, the source gas 3 can hit against the SiC signal crystal having a large diameter and the SiC single crystal can convexly grow with certainty.

The change of the thickness of the diameter narrowing part 8d may be set in such a manner that at least the thickness of the diameter narrowing part 8d decreases toward the center axis of the heating crucible 8. An increasing rate of the thickness of the diameter narrowing part 8d may be decreased with distance from the center axis of the heating crucible 8 as shown in FIG. 5. The growth rate of the SiC single crystal depends on a growth volume in a case where a supplied amount of the source gas 3 is constant and decreases with increase in the diameter of the SiC single crystal. In addition, the increase in the diameter of the SiC single crystal is stopped at a certain level of diameter, and then the SiC single crystal grows with an almost constant diameter. Therefore, when the diameter narrowing part 8d is formed into the above-described shape so that an expansion of the opening size of the opening portion of the diameter narrowing part 8d decelerates, the diameter of the opening portion of the diameter narrowing part 8d can be increased in accordance with the increase in the diameter of the SiC single crystal more certainly.

### Other Embodiments

Although the present invention has been fully described in connection with the preferred embodiments thereof with reference to the accompanying drawings, it is to be noted that various changes and modifications will become apparent to those skilled in the art.

In the second embodiment, the taper part 8e is provided at the opening portion of the diameter narrowing part 8d of the heating crucible 8, as an example. Alternatively, a rear surface side of the diameter narrowing part 8d, that is, a surface of the diameter narrowing part 8d adjacent to the reaction crucible 9 may also be formed into the taper part 8e.

In each of the above-described embodiments, both the pedestal 9a and the seed crystal 5 have circular shape. However, the pedestal 9a and the seed crystal 5 may also have other shapes including square. Also in the present case, the opening portion of the diameter narrowing part 8d is set to be smaller than the dimension of the pedestal 9a (that is, the dimension of the seed crystal 5 disposed on the pedestal 9a).

In each of the above-described embodiments, the heating crucible 8 includes the cylindrical member having the bottom, as an example. The heating crucible 8 may also include merely a hollow cylindrical member without a bottom. The SiC single crystal manufacturing apparatus according to each of the above-described embodiments includes the reaction crucible 9 in which the pedestal 9a is disposed. The SiC single crystal manufacturing apparatus may also include only the pedestal 9a without the reaction crucible 9.

The SiC single crystal manufacturing apparatus according to the second embodiment includes the taper part 8e and the SiC single crystal manufacturing apparatus according to the third embodiment includes the diameter narrowing part 8d whose thickness is changed in accordance with a distance from the center axis of the heating crucible 8. The taper part 8e and the diameter narrowing part 8d whose thickness is changed in accordance with the a distance from the center axis of the heating crucible 8 can be combined.

What is claimed is:

1. A silicon carbide single crystal manufacturing apparatus for growing a silicon carbide single crystal on a surface of a seed crystal that is made of a silicon carbide single crystal substrate by supplying source gas of silicon carbide from under the seed crystal, comprising
a pedestal on which the seed crystal is disposed, and
a heating crucible disposed on an upstream side of a flow channel of the source gas with respect to the pedestal, wherein:
the heating crucible includes a hollow cylindrical member and a diameter narrowing part;
the hollow cylindrical member has an upstream end and a downstream end;
the heating crucible supplies the source gas to the seed crystal by introducing the source gas from the upstream end of the hollow cylindrical member and discharging the source gas from the downstream end of the hollow cylindrical member;
the diameter narrowing part is disposed on the downstream end of the hollow cylindrical member and has an opening portion that is smaller than an opening size of the hollow cylindrical member; and
the whole opening portion of the diameter narrowing part is included in a region that is defined by projecting an outer edge of the pedestal in a center axis direction of the heating crucible.

2. The silicon carbide single crystal manufacturing apparatus according to claim 1, wherein:
the diameter narrowing part has a surface that faces the pedestal;
the diameter narrowing part has a taper part on the surface; and
the taper part has an opening size that gradually increases toward the pedestal.

3. The silicon carbide single crystal according to claim 1, wherein
the diameter narrowing part has a thickness that decreases toward a center axis of the heating crucible.

4. The silicon carbide single crystal according to claim 3, wherein
an increasing rate of the thickness of the diameter narrowing part decreases with distance from the center axis of the heating crucible.

5. A method of manufacturing a silicon carbide single crystal, comprising:
disposing a seed crystal that is made of a silicon carbide single crystal substrate on a pedestal;
disposing a heating crucible on an upstream side of a flow channel of source gas of silicon carbide with respect to the pedestal, the heating crucible including a hollow cylindrical member and a diameter narrowing part, the hollow cylindrical member having an upstream end and a downstream end, the heating crucible supplying the source gas to the seed crystal by introducing the source gas from the upstream end of the hollow cylindrical member and discharging the source gas from the downstream end of the hollow cylindrical member, the diameter narrowing part disposed on the downstream end of the hollow cylindrical member and having an opening portion that is smaller than an opening size of the hollow cylindrical member; and
growing the silicon carbide single crystal on a surface of the seed crystal in such a manner that a flux of the source gas has an in-plane distribution on a growth surface of the silicon carbide single crystal by supplying the source gas through the opening portion of the diameter narrowing part.
